(19) United States
(12) Patent Application Publication
(10) Pub. No.: US 2026/0282600 A1
(43) Pub. Date: Sep. 17, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Jia Liu, Yokohama Kanagawa (JP); Eitaro Miyake, Tachikawa Tokyo (JP)

(21) Appl. No.: 19/359,113

(22) Filed: Oct. 15, 2025

(30) Foreign Application Priority Data
Mar. 17, 2025 (JP) 2025-042791

(51) Int. Cl. H10F 77/00; H10F 39/95; H10H 29/20

(52) U.S. Cl. CPC H10F 77/933; H10F 39/95; H10H 29/20

(57) ABSTRACT

According to one embodiment, a semiconductor device includes a substrate; a first transistor; a second transistor having a gate electrode, and a source electrode coupled commonly with the source electrode of the first transistor; a light emitter; and a light receiver, wherein the gate electrode and the source electrode of the first transistor, and the gate electrode and the source electrode of the second transistor each have a rectangular shape, and the gate electrode and the source electrode of the first transistor and the gate electrode and the source electrode of the second transistor are provided so as to be arranged in a first direction.

### CROSS-REFERENCE TO RELATED APPLICATION

This application is based upon and claims the benefit of priority from Japanese Patent Application No. 2025-042791, filed Mar. 17, 2025, the entire contents of which are incorporated herein by reference.

### FIELD

Embodiments described herein relate generally to a semiconductor device.

### BACKGROUND

As a semiconductor device, a photo relay apparatus including a light emitter and a light receiver is known. The photo relay apparatus is a contactless relay, and is used for transmission of an AC signal and a DC signal.

### BRIEF DESCRIPTION OF DRAWINGS

FIG. 1 is a circuit diagram for explaining an example of a circuit configuration of a semiconductor device according to a first embodiment.

FIG. 2 is a perspective view illustrating an example of a structure of the semiconductor device according to the first embodiment.

FIG. 3 is a plan view illustrating an example of a planar structure of the semiconductor device according to the first embodiment.

FIG. 4 is a plan view illustrating an example of a structure of a semiconductor device according to a comparative example.

FIG. 5 is a plan view illustrating an example of a structure of a semiconductor device according to a first modification of the first embodiment.

FIG. 6 is a plan view illustrating an example of a structure of a semiconductor device according to a second modification of the first embodiment.

FIG. 7 is a plan view illustrating an example of a structure of a semiconductor device according to a second embodiment.

FIG. 8 is a plan view illustrating an example of a structure of a semiconductor device according to a first modification of the second embodiment.

FIG. 9 is a plan view illustrating an example of a structure of a semiconductor device according to a second modification of the second embodiment.

### DETAILED DESCRIPTION

In general, according to one embodiment, a semiconductor device includes a substrate; a first transistor provided above a first surface of the substrate and having a gate electrode and a source electrode; a second transistor provided above the first surface and having a gate electrode, and a source electrode coupled commonly with the source electrode of the first transistor; a light emitter provided above the first surface of the substrate and having an anode electrode and a cathode electrode; and a light receiver that is provided above the first surface of the substrate and turns on or off the first transistor and the second transistor according to a light emission state of the light emitter, wherein the gate electrode and the source electrode of the first transistor, and the gate electrode and the source electrode of the second transistor each have a rectangular shape, and the gate electrode and the source electrode of the first transistor and the gate electrode and the source electrode of the second transistor are provided so as to be arranged in a first direction in the first surface.

Hereinafter, embodiments will be described with reference to the drawings. Note that in the following description, components having the same function and configuration are denoted by the common reference numerals. In addition, dimensions and ratios of the drawings are not necessarily the same as actual ones.

### 1 First Embodiment

A semiconductor device according to a first embodiment will be described.

The semiconductor device according to the first embodiment is, for example, a photo relay apparatus for transmitting an AC signal or a DC signal. The semiconductor device according to the first embodiment is, for example, a package of an electronic component. In the following description, the AC signal and the DC signal are also simply referred to as signals.

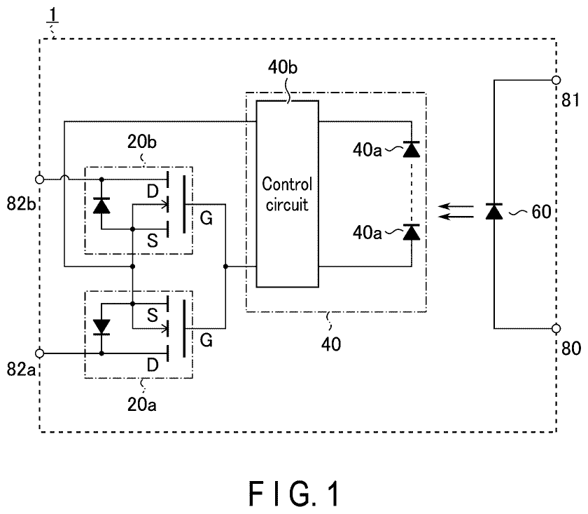

An example of a circuit configuration of the semiconductor device according to the first embodiment will be described with reference to FIG. 1. FIG. 1 is a circuit diagram for explaining the example of the circuit configuration of the semiconductor device according to the first embodiment.

The semiconductor device 1 includes terminals 80, 81, 82a, and 82b. A voltage for driving the semiconductor device 1 is supplied to the terminals 80 and 81. While the semiconductor device 1 is driven, the semiconductor device 1 can transmit signals via the terminals 82a and 82b.

The semiconductor device 1 further includes metal-oxide-semiconductor field effect transistors (MOSFET) 20a and 20b, a light receiver 40, and a light emitter 60. The MOSFETs 20a and 20b are, for example, enhancement type N-channel MOSFETs. The light receiver 40 is, for example, a sensor including a photo diode array (PDA) or a phototransistor. Hereinafter, a case where the light receiver 40 includes a PDA will be described. The light emitter 60 is, for example, a light emitting diode (LED).

The light emitter 60 is coupled to the terminals 80 and 81. More specifically, an anode electrode of the light emitter 60 is coupled to, for example, the terminal 80. A cathode electrode of the light emitter 60 is coupled to, for example, the terminal 81. The light emitter 60 is driven by power supplied to the terminals 80 and 81. As a result, a light emission state of the light emitter 60 is brought to an on state (lighting state) or an off state (non-lighting state).

The light receiver 40 includes, for example, a plurality of photodiodes 40a coupled in series and a control circuit 40b. The number of the photodiodes 40a is, for example, several to several tens. Opposite ends of the plurality of photodiodes 40a coupled in series are each coupled to the control circuit 40b. The control circuit 40b turns on the MOSFETs 20a and 20b using photovoltaic power generated by the plurality of photodiodes 40a.

A gate of the MOSFET 20a and a gate of the MOSFET 20b are commonly coupled to an anode electrode of the light receiver 40. A source of the MOSFET 20a and a source of the MOSFET 20b are commonly coupled to a cathode electrode of the light receiver 40. A drain of the MOSFET 20a is coupled to the terminal 82a. A drain of the MOSFET 20b is coupled to the terminal 82b.

In the circuit configuration of the semiconductor device 1 as described above, when the light emitter 60 is brought from the off state to the on state, light is emitted from the light emitter 60. The light receiver 40 changes the MOSFETs 20a and 20b from an off state to an on state using a voltage generated by a photovoltaic effect by the light of the light emitter 60. As a result, the terminals 82a and 82b are electrically coupled. In this manner, the semiconductor device 1 transmits a signal supplied to one terminal of the terminals 82a and 82b to the other terminal of the terminals 82a and 82b via the MOSFETs 20a and 20b.

In addition, when the light emitter 60 is brought from the on state to the off state, the light irradiation from the light emitter 60 is stopped. As a result, the MOSFETs 20a and 20b change from the on state to the off state. In this manner, the semiconductor device 1 electrically insulates the terminals 82a and 82b from each other.

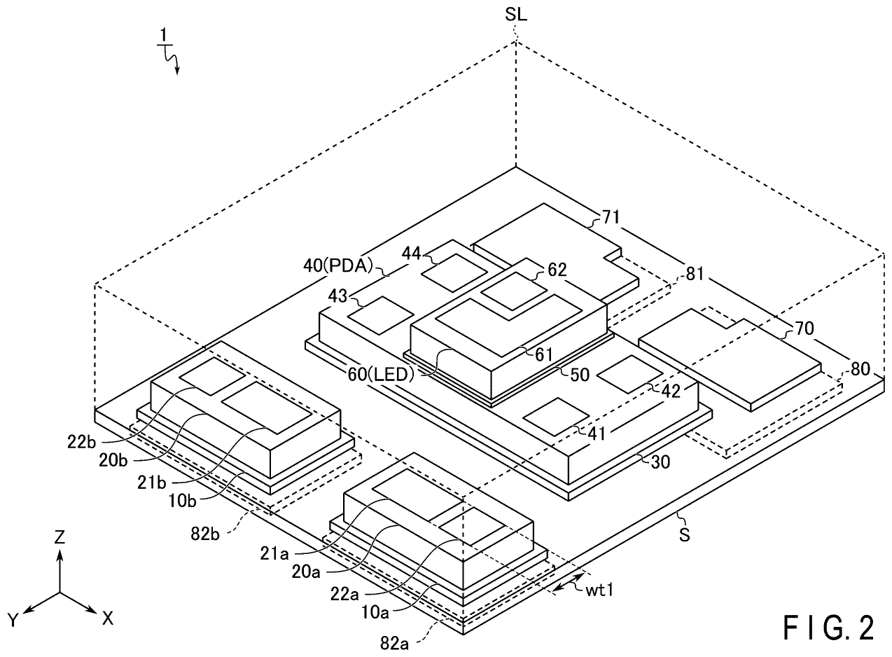

Next, a structure of the semiconductor device 1 according to the first embodiment will be described with reference to FIG. 2. FIG. 2 is a perspective view illustrating an example of the structure of the semiconductor device according to the first embodiment. In the following description, a Z direction corresponds to a direction perpendicular to a surface of a substrate on which the semiconductor device 1 is formed. An X direction is a direction parallel to the surface of the substrate. A Y direction is a direction parallel to the surface of the substrate and perpendicular to the X direction. Note that in FIG. 2, illustration of a wiring is omitted for easy understanding of the drawing. The wiring will be described later.

The semiconductor device 1 further includes a substrate S, electrodes 10a, 10b, 70, and 71, a support base 30, an adhesive layer 50, and a sealing material SL. In the following description, the electrode can also be referred to as a pad. Note that in the following description, of the substrate S and the MOSFET 20a, a side on which the MOSFET 20a is provided is referred to as an upper side along the Z direction. Of the substrate S and the MOSFET 20a, a side on which the substrate S is provided is referred to as a lower side along the Z direction.

The substrate S is, for example, a circuit board using bismaleimide triazine (BT) resin or a flexible printed circuit (FPC) using polyimide.

The electrodes 10a, 10b, 70, and 71 are provided on an upper surface of the substrate S. The electrodes 10a, 10b, 70, and 71 are, for example, metal foils containing copper. The electrodes 10a, 10b, 70, and 71 are provided such that, for example, the electrodes 10a and 10b, and the electrodes 70 and 71 are arranged in the Y direction. In the following description, of the electrodes 10a, 10b, 70, and 71, a side on which the electrodes 10a and 10b are provided is referred to as one end side along the Y direction. Of the electrodes 10a, 10b, 70, and 71, a side on which the electrodes 70 and 71 are provided is referred to as the other end side along the Y direction. The electrodes 10a and 10b are arranged in the X direction, for example. In the following description, of the electrodes 10a and 10b, a side on which the electrode 10a is provided is referred to as one end side along the X direction. Of the electrodes 10a and 10b, a side on which the electrode 10b is provided is referred to as the other end side along the X direction. The electrodes 70 and 71 are arranged in the X direction, for example. The electrode 70 is provided, for example, on one end side along the X direction with respect to the electrode 71.

The MOSFET 20a includes electrodes 21a and 22a and an electrode disposed in a lower part of the MOSFET 20a (not illustrated in FIG. 2). The electrodes 21a and 22a are provided, for example, so as to be exposed on an upper surface of the MOSFET 20a. The electrodes 21a and 22a have, for example, a rectangular shape. The electrodes 21a and 22a have, for example, substantially the same width wt1 in the Y direction. Note that a width of the electrode 21a in the Y direction may be different from a width of the electrode 22a in the Y direction. The electrodes 21a and 22a are arranged in the X direction. The electrode 21a is provided, for example, on the other end side along the X direction with respect to the electrode 22a. The electrode disposed in the lower part of the MOSFET 20a is in contact with the electrode 10a via a conductive paste or the like on a lower surface of the MOSFET 20a, for example. Note that the electrode disposed in the lower part of the MOSFET 20a can have, for example, the same size as the lower surface of the MOSFET 20a. The electrode 21a functions as a source electrode of the MOSFET 20a. The electrode 22a functions as a gate electrode of the MOSFET 20a. The electrode disposed in the lower part of the MOSFET 20a functions as a drain electrode of the MOSFET 20a.

The MOSFET 20b includes electrodes 21b and 22b and an electrode disposed in a lower part of the MOSFET 20b (not illustrated in FIG. 2). The electrodes 21b and 22b are provided so as to be exposed on an upper surface of the MOSFET 20b. The electrodes 21b and 22b have, for example, a rectangular shape. The electrodes 21b and 22b have substantially the same width wt1 in the Y direction, for example, similarly to the electrodes 21a and 22a. Note that a width of the electrode 21b in the Y direction may be different from a width of the electrode 22b in the Y direction. The electrodes 21b and 22b are arranged in the X direction. The electrode 21b is provided, for example, on one end side along the X direction with respect to the electrode 22b. The electrode disposed in the lower part of the MOSFET 20b is in contact with the electrode 10b via a conductive paste or the like on a lower surface of the MOSFET 20b. Note that the electrode disposed in the lower part of the MOSFET 20b can have, for example, the same size as the lower surface of the MOSFET 20b. The electrode 21b functions as a source electrode of the MOSFET 20b. The electrode 22b functions as a gate electrode of the MOSFET 20b. The electrode disposed in the lower part of the MOSFET 20b functions as a drain electrode of the MOSFET 20b.

With the arrangement of the MOSFETs 20a and 20b as described above, the MOSFETs 20a and 20b are, for example, arranged adjacent to each other in the X direction. As a result, the electrodes 21a, 21b, 22b, and 22a are linearly arranged in this order along the X direction.

The support base 30 is provided on the upper surface of the substrate S. The support base 30 is provided so as to be sandwiched in the Y direction by, for example, the electrodes 10a and 10b and the electrodes 70 and 71. The support base 30 has a plate shape extending in the X direction and the Y direction. The support base 30 supports the light receiver 40 and the light emitter 60. The support base 30 may be, for example, either a conductor or an insulator. Furthermore, the support base 30 may be, for example, a composite material of a conductor and an insulator.

The light receiver 40 is provided so as to be in contact with an upper surface of the support base 30. Furthermore, the light receiver 40 is arranged such that, for example, the light receiver 40 has a light receiving surface on an upper surface of the light receiver 40.

The light receiver 40 includes electrodes 41, 42, 43, and 44. The electrodes 41 to 44 are provided so as to be exposed on the upper surface of the light receiver 40. Although not illustrated in FIG. 2, the electrodes 41 and 43 are electrically coupled in the light receiver 40, for example. Although not illustrated in FIG. 2, the electrodes 42 and 44 are electrically coupled in the light receiver 40, for example. The electrodes 41 and 43 function as, for example, the cathode electrode of the light receiver 40. The electrodes 42 and 44 function as, for example, the anode electrode of the light receiver 40.

The light emitter 60 is provided above the light receiver 40. The light emitter 60 is disposed so as to have a light irradiation surface on a lower surface of the light emitter 60. The irradiation surface of the light emitter 60 is opposed to a light receiving surface of the light receiver 40.

The light emitter 60 includes electrodes 61 and 62. The electrodes 61 and 62 are disposed on an upper surface of the light emitter 60. The electrode 61 functions as, for example, the anode electrode of the light emitter 60. The electrode 62 functions as, for example, the cathode electrode of the light emitter 60.

The adhesive layer 50 in contact with each of the light emitter 60 and the light receiver 40 is provided between the light emitter 60 and the light receiver 40. The adhesive layer 50 is, for example, an insulating material having transparency with respect to light emitted from the light emitter 60.

Each of the terminals 80, 81, 82a, and 82b is provided, for example, such that an upper surface of the terminal is in contact with a lower surface of the substrate S.

A signal is transmitted between the terminals 80 and 81 by, for example, an equipment, a circuit, or the like (not illustrated). Although not illustrated in FIG. 2, the terminal 80 is electrically coupled to the electrode 70 via, for example, a conductor (via) penetrating the substrate S. In addition, although not illustrated in FIG. 2, the terminal 81 is electrically coupled to the electrode 71 via a conductor (via) penetrating the substrate S, for example, similarly to the terminal 80.

The terminals 82a and 82b are each coupled to a circuit or the like provided outside the semiconductor device 1. Although not illustrated in FIG. 2, the terminal 82a is electrically coupled to the electrode disposed in the lower part of the MOSFET 20a via the conductor (via) penetrating the substrate S, the electrode 10a, and a conductive paste. In addition, although not illustrated in FIG. 2, for example, similarly to the terminal 82a, the terminal 82b is electrically coupled to the electrode disposed in the lower part of the MOSFET 20b via the conductor (via) penetrating the substrate S, the electrode 10b, and a conductive paste.

Each of the terminals 82a and 82b can be electrically coupled to, for example, a wiring provided outside the semiconductor device 1. The terminals 82a and 82b can also be referred to as mounting pads. The semiconductor device 1 and such a wiring are provided above a mounting board outside the semiconductor device 1.

The sealing material SL is provided so as to cover the MOSFETs 20a and 20b, the support base 30, the light receiver 40, the light emitter 60, and the electrodes 10a, 10b, 70, and 71. The sealing material SL may include, for example, a non-translucent material.

In the configuration of the semiconductor device 1 as described above, the electrodes 10a, 10b, 70, and 71 and the MOSFETs 20a and 20b can be arranged, for example, symmetrically with respect to a YZ plane.

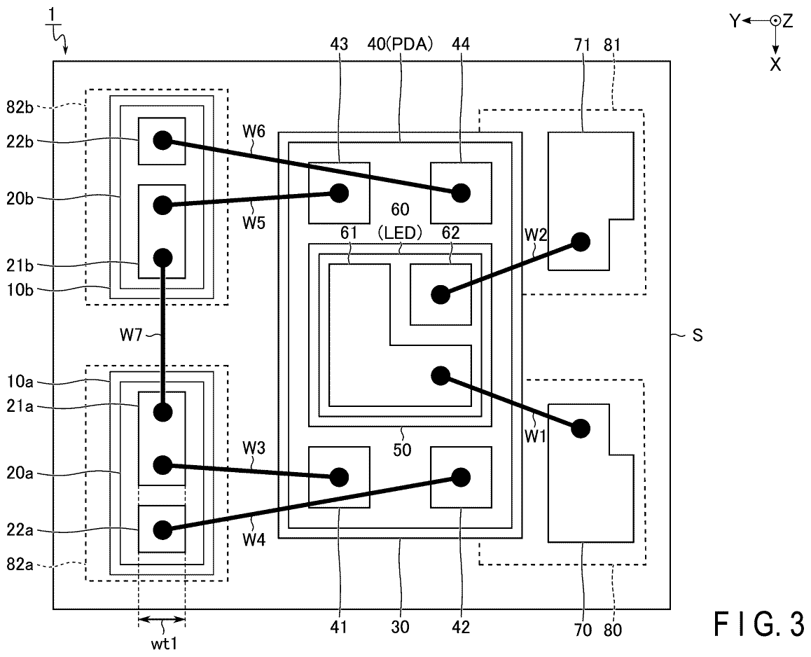

A wiring inside the semiconductor device 1 will be described with reference to FIG. 3. FIG. 3 is a plan view illustrating an example of a planar structure of the semiconductor device according to the first embodiment.

The semiconductor device 1 further includes wirings W1, W2, W3, W4, W5, W6, and W7.

The wirings W1 to W7 are, for example, wires formed by wire bonding. The wirings W1 to W7 are made of a conductive material.

The wiring W1 electrically couples the electrode 61 and the electrode 70. The wiring W2 electrically couples the electrode 62 and the electrode 71. The wiring W3 electrically couples the electrode 41 and the electrode 21a. The wiring W4 electrically couples the electrode 42 and the electrode 22a. The wiring W5 electrically couples the electrode 43 and the electrode 21b. The wiring W6 electrically couples the electrode 44 and the electrode 22b. The wiring W7 electrically couples the electrodes 21a and 21b.

Although in FIG. 3, the electrodes 21a and 21b are electrically coupled by one wiring W7, the present invention is not limited thereto. The electrodes 21a and 21b may be electrically coupled by two or more wirings W7.

The wirings W1 to W7 are covered with the sealing material SL (not illustrated in FIG. 3).

The wirings W1 to W7 can be disposed, for example, symmetrically with respect to the YZ plane.

According to the first embodiment, it is possible to suppress an increase in the mounting area of the semiconductor device 1. Hereinafter, suppression of the increase in the mounting area by the semiconductor device 1 according to the first embodiment will be described.

The semiconductor device 1 according to the first embodiment includes the substrate S, the MOSFETs 20a and 20b, the light receiver 40, and the light emitter 60. The light receiver 40 turns on or off the MOSFETs 20a and 20b according to the light emission state of the light emitter 60. Each of the electrodes 21a, 21b, 22a, and 22b has a rectangular shape. In addition, in the MOSFET 20a, the electrodes 21a and 22a are provided so as to be arranged in the X direction. In addition, in the MOSFET 20b, the electrodes 21b and 22b are provided so as to be arranged in the X direction, similarly to the electrodes 21a and 22a. As described above, since the electrodes 21a, 21b, 22a, and 22b have rectangular shapes, an increase in areas of the MOSFETs 20a and 20b is suppressed. In addition, in the semiconductor device 1 including the MOSFETs 20a and 20b, the electrodes 21a and 22a and the electrodes 21b and 22b are arranged in the same direction, so that the increase in the mounting area of the semiconductor device 1 is suppressed.

More specifically, according to the semiconductor device 1 of the first embodiment, the electrodes 21a, 21b, 22a, and 22b are disposed so as to be linearly arranged along the X direction. As a result, in the semiconductor device 1 in which, of the X direction and the Y direction, the Y direction is a longitudinal direction, it is possible to suppress an increase in a length of the semiconductor device 1 in the Y direction. Therefore, the increase in the mounting area of the semiconductor device 1 is suppressed.

Furthermore, the semiconductor device 1 according to the first embodiment enables a deterioration of pass characteristics of the semiconductor device 1 to be suppressed with the above-described configuration.

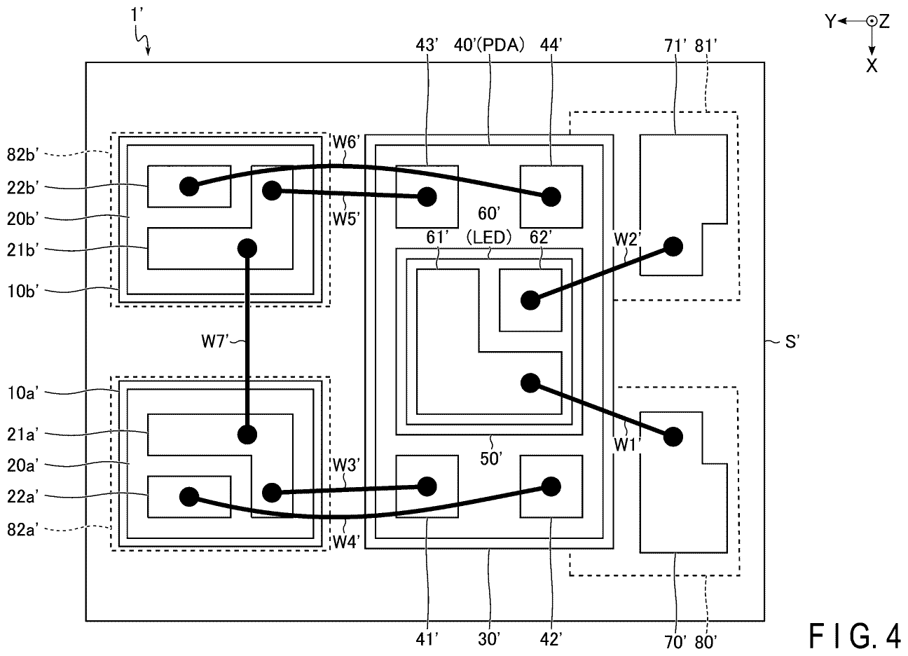

The suppression of the deterioration of the pass characteristics will be described using a photo relay apparatus of a comparative example illustrated in FIG. 4. FIG. 4 is a plan view illustrating an example of a structure of a semiconductor device according to the comparative example. A photo relay apparatus 1′ of the comparative example includes a substrate S′, electrodes 10a′, 10b′, 70′, and 71′, MOSFETs 20a′ and 20b′, a support base 30′, a light receiver 40′, an adhesive layer 50′, a light emitter 60′, terminals 80′, 81′, 82a′, and 82b′, and wires W1′ to W7′. The MOSFET 20a′ includes electrodes 21a′ and 22a′. The MOSFET 20b′ includes electrodes 21b′ and 22b′. The light emitter 60′ includes electrodes 61′ and 62′. The substrate S′, the electrodes 10a′, 10b′, 70′, and 71′, the MOSFETs 20a′ and 20b′, the support base 30′, the light receiver 40′, the adhesive layer 50′, the light emitter 60′, the terminals 80′, 81′, 82a′, and 82b′, and the wires W1′ to W7′ correspond respectively to the substrate S, the electrodes 10a, 10b, 70, and 71, the MOSFETs 20a and 20b, the support base 30, the light receiver 40, the adhesive layer 50, the light emitter 60, the terminals 80, 81, 82a, and 82b, and the wires W1 to W7 of the first embodiment. The electrodes 21b′, 22b′, 61′, and 62′ correspond to the electrodes 21b, 22b, 61, and 62 of the first embodiment, respectively. The electrode 21a′ (source electrode) of the MOSFET 20a′ and the electrode 21b′ (source electrode) of the MOSFET 20b′ of the comparative example each have an L shape (bent shape) when viewed from above.

The photo relay apparatus is mounted on, for example, a mounting board in series of an insulator layer. In order to suppress an increase in size of an apparatus including the photo relay apparatus, it is required to thin the mounting board and thin a wiring pattern. However, when the mounting board is thinned, a characteristic impedance of the wiring collapses, so that it is necessary to reduce a wiring width of the mounting board. In addition, in a case where the wiring width of the mounting board is thus reduced, a width of a mounting pad of the MOSFET also needs to be reduced. In a case where the width of the mounting pad of the MOSFET (a size of the MOSFET) cannot be reduced, impedance mismatch occurs. In addition, this deteriorates the pass characteristics of the photo relay apparatus. In a case of using the photo relay apparatus 1′ of the comparative example, due to the structure of the L-shaped source electrodes (the electrodes 21a′ and 21b′), it may be difficult to reduce the width of the mounting pad (the width in the Y direction in FIG. 4) and the size of the MOSFET. For this reason, impedance mismatch might occur, and the pass characteristics of the photo relay apparatus might be deteriorated.

According to the first embodiment, with the above-described configuration, in the semiconductor device 1 in which, of the X direction and the Y direction, the Y direction is the longitudinal direction, an increase in a width of the MOSFETs 20a and 20b in the Y direction is suppressed. As a result, an increase in a width of the terminals 82a and 82b in the Y direction is suppressed. Therefore, even in a case where a thickness of the mounting board is reduced, impedance mismatch can be suppressed. Therefore, deterioration of the pass characteristics of the semiconductor device 1 can be suppressed.

According to the first embodiment, the electrodes 21a, 21b, 22b, and 22a are arranged in this order. In other words, the source electrode of the MOSFET 20a and the source electrode of the MOSFET 20b are provided so as to be adjacent to each other in the X direction. According to such a configuration, the source electrode of the MOSFET 20a and the source electrode of the MOSFET 20b can be easily coupled. In addition, by arranging the electrodes 21a, 21b, 22b, and 22a in one direction, the wiring can be easily disposed.

### 2 Modifications of First Embodiment

Next, a semiconductor device according to a modification of the first embodiment will be described. Hereinafter, description of configurations equivalent to those of the first embodiment will be omitted, and configurations different from those of the first embodiment will be mainly described.

### 2.1 First Modification of First Embodiment

Although in the first embodiment described above, the electrode of the light receiver and the source of one MOSFET, the electrode of the light receiver and the source of the other MOSFET, and the source of one MOSFET and the source of the other MOSFET are electrically coupled by different wirings, the present invention is not limited thereto. The light receiver, the source of one MOSFET, and the source of the other MOSFET may be electrically coupled by one wiring.

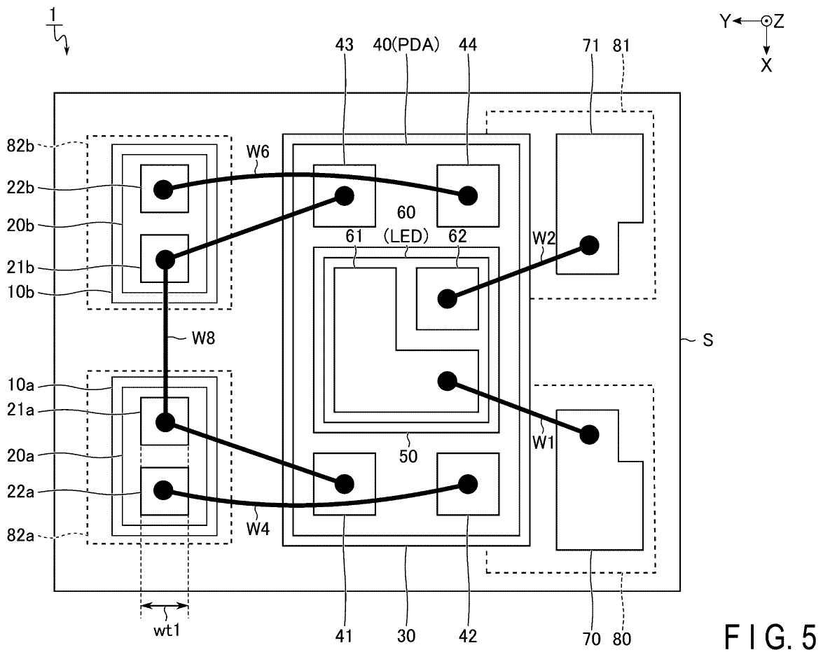

A configuration of a semiconductor device 1 according to a first modification of the first embodiment will be described with reference to FIG. 5. FIG. 5 is a plan view illustrating an example of a structure of the semiconductor device according to the first modification of the first embodiment.

The semiconductor device 1 according to the first modification of the first embodiment includes a wiring W8 instead of the wirings W3, W5, and W7.

An electrode 41 of a light receiver 40, an electrode 21a of a MOSFET 20a, an electrode 21b of a MOSFET 20b, and an electrode 43 of a light receiver 40 are electrically coupled in series by one wiring W8. The wiring W8 has, for example, one joint portion on each of the electrodes 21a, 21b, 41, and 43. In addition, the wiring W8 has, for example, three loops provided between the electrodes 21a and 41, between the electrodes 21a and 21b, and between the electrodes 21b and 43. The wiring W8 and the electrodes 21a, 21b, 41, and 43 are joined by wedge bonding, for example. The wiring W8 is made of a conductive material.

The first modification of the first embodiment also achieves effects similar to those of the first embodiment.

In addition, according to the first modification of the first embodiment, the electrodes 21a, 21b, 41, and 43 are electrically coupled by one wiring W8. This also makes it possible to suppress an increase in a mounting area of the semiconductor device 1. As a supplement, in the first modification of the first embodiment, the electrodes 21b and 41 are electrically coupled via one joint portion provided on the electrode 21a. In addition, the electrodes 21a and 43 are electrically coupled via one joint portion provided on the electrode 21b, similarly to the connection of the electrodes 21b and 41. With the above configuration, it is possible to suppress an increase in areas of the electrode 21a of the MOSFET 20a and the electrode 21b of the MOSFET 20b. Therefore, it is possible to suppress an increase in the mounting area of the semiconductor device 1.

Furthermore, according to the first modification of the first embodiment, at the time of forming a wire between the light receiver 40 (PDA), and the MOSFETs 20a and 20b by wire bonding, it is not necessary to cut the wire at an intermediate joint part (the electrode 21a of the MOSFET 20a and the electrode 21b of the MOSFET 20b), so that mountability can be improved.

### 2.2 Second Modification of First Embodiment

Although the first embodiment described above shows the case where the four electrodes are provided on the upper surface of the light receiver, the present invention is not limited thereto. The light receiver may have two electrodes on its upper surface.

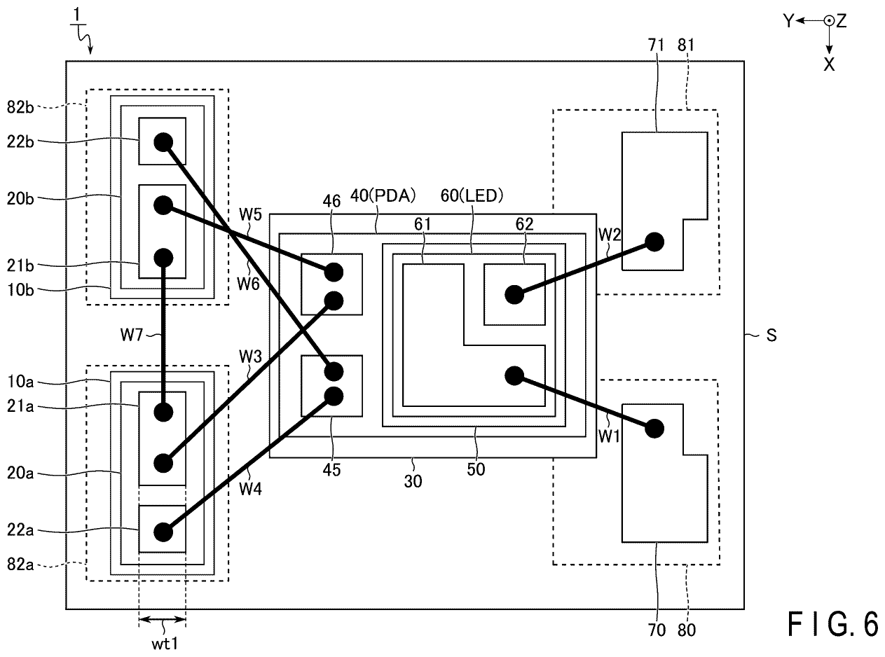

Hereinafter, a configuration of a semiconductor device 1 according to a second modification of the first embodiment will be described with reference to FIG. 6. FIG. 6 is a plan view illustrating an example of a structure of the semiconductor device according to the second modification of the first embodiment.

In the second modification of the first embodiment, a light receiver 40 includes electrodes 45 and 46 instead of the electrodes 41 to 44. The electrodes 45 and 46 are provided so as to be exposed on an upper surface of the light receiver 40. The electrode 45 functions as, for example, an anode electrode of the light receiver 40. In other words, the electrode 45 corresponds to the electrodes 42 and 44 of the first embodiment. The electrode 46 functions as, for example, a cathode electrode of the light receiver 40. In other words, the electrode 46 corresponds to the electrodes 41 and 43 of the first embodiment. The electrodes 45 and 46 are provided, for example, on one end side of the light receiver 40 along the Y direction when viewed from above. Furthermore, the electrodes 45 and 46 are provided, for example, on one end side along the Y direction with respect to a light emitter 60.

A wiring W3 electrically couples the electrode 46 and an electrode 21a. A wiring W4 electrically couples the electrode 45 and an electrode 22a. A wiring W5 electrically couples the electrode 46 and an electrode 21b. A wiring W6 electrically couples the electrode 45 and an electrode 22b.

The second modification of the first embodiment also achieves effects similar to those of the first embodiment.

According to the second modification of the first embodiment, the electrode 45 of the light receiver 40 is electrically coupled to each of the electrodes 22a and 22b, and the electrode 46 of the light receiver 40 is electrically coupled to each of the electrodes 21a and 21b, so that an increase in a mounting area of the semiconductor device 1 can be suppressed.

### 3 Second Embodiment

Although in the first embodiment, the source electrode and the gate electrode of one MOSFET and the source electrode and the gate electrode of the other MOSFET are arranged in the X direction, the present invention is not limited thereto. The source electrode and the gate electrode of one MOSFET and the source electrode and the gate electrode of the other MOSFET may be arranged in parallel. Hereinafter, description of configurations equivalent to those of the first embodiment will be omitted, and configurations different from those of the first embodiment will be mainly described.

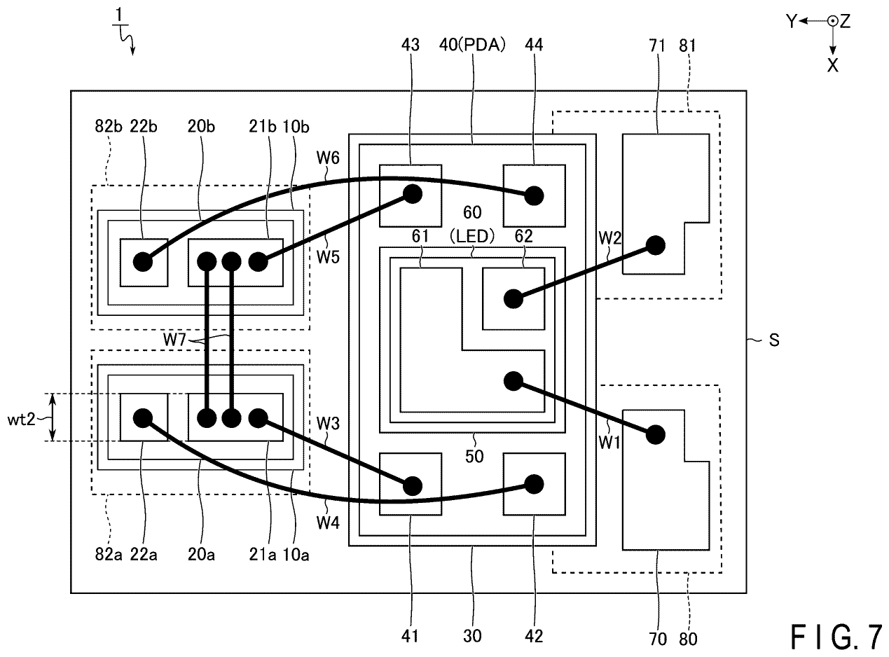

A configuration of a semiconductor device 1 according to a second embodiment will be described with reference to FIG. 7. FIG. 7 is a plan view illustrating an example of a structure of the semiconductor device according to the second embodiment.

In a MOSFET 20a, electrodes 21a and 22a are arranged in the Y direction. The electrodes 21a and 22a have, for example, substantially the same width wt2 in the X direction. Note that a width of the electrode 21a in the Y direction may be different from a width of the electrode 22a in the Y direction. The electrode 21a is provided, for example, on one end side in the Y direction with respect to the electrode 22a.

In a MOSFET 20b, electrodes 21b and 22b are arranged in the Y direction. The electrodes 21b and 22b have, for example, substantially the same width wt2 in the X direction. Note that a width of the electrode 21b in the Y direction may be different from a width of the electrode 22b in the Y direction. The electrode 21b is provided, for example, on one end side in the Y direction with respect to the electrode 22b.

With the configuration of the MOSFETs 20a and 20b as described above, the electrodes 21a and 22a, and the electrodes 21b and 22b are arranged in parallel in the Y direction. The electrodes 21a and 21b are arranged in the X direction, for example. The electrodes 22a and 22b are arranged in the X direction, for example.

Although illustrated in the example illustrated in FIG. 7 is a case where the electrodes 21a and 21b are electrically coupled by two wirings W7, the present invention is not limited thereto. The electrodes 21a and 21b may be electrically coupled by one or three or more wirings W7.

Also in the second embodiment, similarly to the first embodiment, an increase in a mounting area of the semiconductor device 1 can be suppressed. As a supplement, by arranging the electrodes 21a and 22a, and the electrodes 21b and 22b in the Y direction, an increase in widths of the MOSFETs 20a and 20b in the X direction can be suppressed. Therefore, it is possible to suppress the increase in the mounting area of the semiconductor device 1.

### 4 Modifications of Second Embodiment

Next, a semiconductor device according to a modification of the second embodiment will be described. Hereinafter, description of configurations equivalent to those of the second embodiment will be omitted, and configurations different from those of the second embodiment will be mainly described.

### 4.1 First Modification of Second Embodiment

Although in the second embodiment described above, the electrode of the light receiver and the source of one MOSFET, the electrode of the light receiver and the source of the other MOSFET, and the source of one MOSFET and the source of the other MOSFET are respectively electrically coupled by different wirings, the present invention is not limited thereto. In the semiconductor device, similarly to the first modification of the first embodiment, the light receiver, the source electrode of one MOSFET, and the source electrode of the other MOSFET may be electrically coupled in series by one wiring.

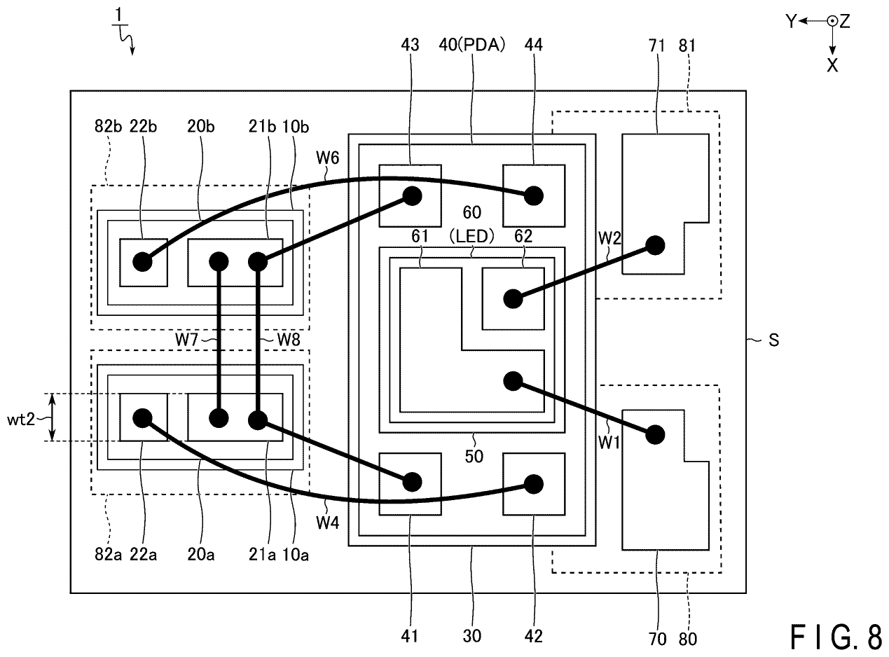

A configuration of a semiconductor device 1 according to a first modification of the second embodiment will be described with reference to FIG. 8. FIG. 8 is a plan view illustrating an example of a structure of the semiconductor device according to the first modification of the second embodiment.

The semiconductor device 1 according to the first modification of the second embodiment includes, for example, a wiring W8 instead of the wirings W3 and W5.

Similarly to the first modification of the first embodiment, electrodes 41, 21a, 21b, and 43 are electrically coupled in series by one wiring W8 in this order.

Note that in the example illustrated in FIG. 8, the electrodes 21a and 21b are also electrically coupled by one wiring W7. However, the present invention is not limited thereto. The electrodes 21a and 21b may be electrically coupled by two or more wirings W7, or may not have the wiring W7.

The first modification of the second embodiment also achieves effects similar to those of the second embodiment.

In addition, according to the first modification of the second embodiment, since the electrodes 21a, 21b, 41, and 43 are electrically coupled by one wiring W8, it is possible to suppress an increase in a mounting area of the semiconductor device 1 for the same reason as in the first modification of the first embodiment.

Furthermore, according to the first modification of the second embodiment, it is possible to suppress a decrease in the number of wirings between the electrodes 21a and 21b. In other words, the electrodes 21a and 21b can be electrically coupled by one or more wirings W7 in addition to the wiring W8. This makes it possible to suppress an increase in a resistance of electrical connection between the electrodes 21a and 21b. Therefore, deterioration of transmission characteristics of the semiconductor device 1 can be suppressed.

Furthermore, according to the first modification of the second embodiment, similarly to the first modification of the first embodiment, at the time of forming a wire between a light receiver 40 (PDA), and MOSFETs 20a and 20b by wire bonding, it is not necessary to cut the wire at an intermediate joint part (the electrode 21a of the MOSFET 20a and the electrode 21b of the MOSFET 20b), so that mountability can be improved.

### 4.2 Second Modification of Second Embodiment

Although illustrated in the second embodiment described above is a case where the four electrodes are provided on the upper surface of the light receiver, the present invention is not limited thereto. Similarly to the second modification of the first embodiment, the light receiver may have two electrodes on the upper surface thereof.

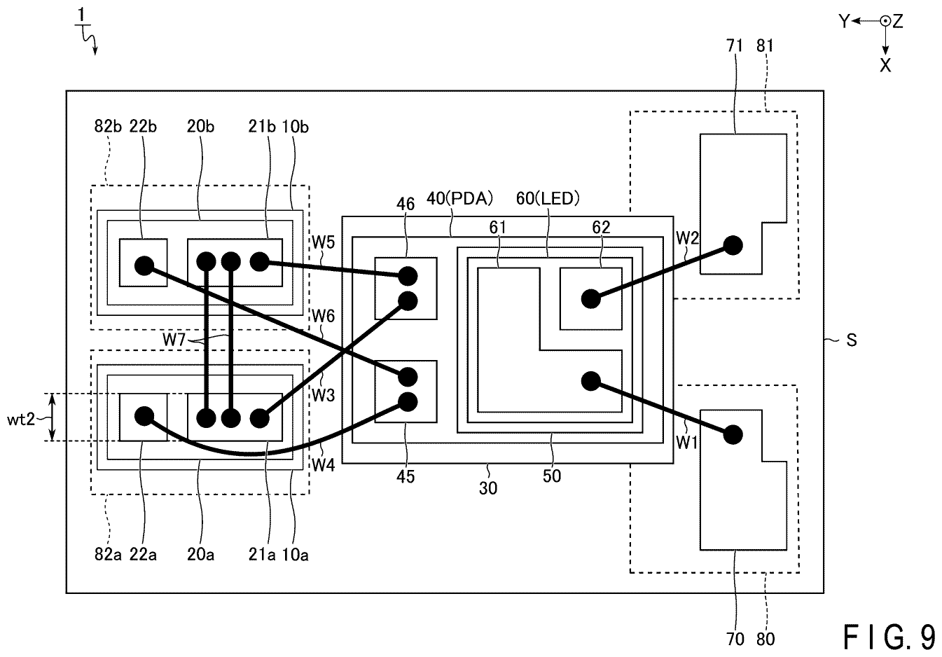

Hereinafter, a configuration of a semiconductor device 1 according to a second modification of the second embodiment will be described with reference to FIG. 9. FIG. 9 is a plan view illustrating an example of a structure of the semiconductor device according to the second modification of the second embodiment.

A configuration of a light receiver 40 in the second modification of the second embodiment is substantially equivalent to the configuration of the light receiver 40 in the second modification of the first embodiment.

In addition, configurations of wirings W1 to W7 are also substantially equivalent to those in the second modification of the first embodiment. FIG. 9 shows an example in which electrodes 21a and 21b are electrically coupled by two wirings W7.

The second modification of the second embodiment also achieves effects similar to those of the second embodiment.

In addition, also according to the second modification of the second embodiment, it is possible to suppress deterioration of transmission characteristics of the semiconductor device 1 in a high frequency range for the same reason as the first modification of the second embodiment.

### 5 Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first transistor provided above a first surface of the substrate and having a gate electrode and a source electrode;
a second transistor provided above the first surface and having a gate electrode, and a source electrode coupled commonly with the source electrode of the first transistor;
a light emitter provided above the first surface of the substrate and having an anode electrode and a cathode electrode; and
a light receiver that is provided above the first surface of the substrate and turns on or off the first transistor and the second transistor according to a light emission state of the light emitter, wherein
the gate electrode and the source electrode of the first transistor, and the gate electrode and the source electrode of the second transistor each have a rectangular shape, and
the gate electrode and the source electrode of the first transistor and the gate electrode and the source electrode of the second transistor are provided so as to be arranged in a first direction in the first surface.

2. The semiconductor device according to claim 1, wherein
the light receiver includes a first electrode and a second electrode electrically coupled to the source electrode of the first transistor and the source electrode of the second transistor, respectively.

3. The semiconductor device according to claim 2, further comprising a first wiring, wherein
the first wiring couples, in series by one wiring, a portion between an upper surface of the first electrode and an upper surface of the source electrode of the first transistor, a portion between the upper surface of the source electrode of the first transistor and an upper surface of the source electrode of the second transistor, and a portion between the upper surface of the source electrode of the second transistor and an upper surface of the second electrode.

4. The semiconductor device according to claim 3,
further comprising:
a second wiring that electrically couples the source electrode of the first transistor and the source electrode of the second transistor and is different from the first wiring.

5. The semiconductor device according to claim 1, wherein
the gate electrode and the source electrode of the first transistor, and the source electrode and the gate electrode of the second transistor are arranged linearly in this order in the first direction.

6. The semiconductor device according to claim 5, wherein
the light emitter and the light receiver, and the first transistor and the second transistor are arranged in a second direction in the first surface intersecting the first direction.

7. The semiconductor device according to claim 1, wherein
the gate electrode and the source electrode of the first transistor are arranged in the first direction,
the gate electrode and the source electrode of the second transistor are arranged in the first direction, and
the source electrode of the first transistor and the source electrode of the second transistor are arranged in a second direction in the first surface intersecting the first direction.

8. The semiconductor device according to claim 7, wherein
the light emitter and the light receiver, and the first transistor and the second transistor are arranged in the first direction.

9. The semiconductor device according to claim 1, wherein
the light receiver
further includes:
a first electrode to be electrically coupled to the gate electrode of the first transistor and the gate electrode of the second transistor; and
a second electrode to be electrically coupled to the source electrode of the first transistor and the source electrode of the second transistor,
a portion between an upper surface of the first electrode and the gate electrode of the first transistor and a portion between the upper surface of the first electrode and the gate electrode of the second transistor are coupled by two different wirings, and
a portion between an upper surface of the second electrode and the source electrode of the first transistor and a portion between the upper surface of the second electrode and the source electrode of the second transistor are coupled by two different wirings.

10. The semiconductor device according to claim 9, wherein
the light receiver has a light receiving surface provided in a portion of an upper surface,
the light emitter is provided above the light receiver such that a light irradiation surface is opposed to the light receiving surface, and
the first transistor and the second transistor, the first electrode and the second electrode, and the light emitter are arranged in this order in the first direction.

11. The semiconductor device according to claim 10, wherein
the source electrode of the first transistor and the source electrode of the second transistor are respectively provided between the gate electrode of the first transistor and the gate electrode of the second transistor, and the light receiver in the first direction.
